(19) United States
(12) Patent Application Publication
(10) Pub. No.: US 2026/0096108 A1
(43) Pub. Date: Apr. 2, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Jen-Pan Wang, Tainan (TW); Chia-Ming Huang, Tainan City (TW)

(73) Assignee: Taiwan Semiconductor Manufacturing Company, Ltd., Hsinchu (TW)

(21) Appl. No.: 18/903,787

(22) Filed: Oct. 1, 2024

(51) Int. Cl. H01L 23/528; H01L 27/06

(52) U.S. Cl. CPC H10D 1/20; H10D 84/40; H10W 20/43; H10W 20/435

(57) ABSTRACT

Semiconductor devices and fabrication methods are disclosed. A fabrication method involves forming, on a substrate, a transistor comprising a source, drain, and gate, forming, on the substrate, an interconnect layer configured to provide electrical connections for the source, drain, and gate, the interconnect layer comprising regions of metal material disposed within a layer of dielectric material, wherein the interconnect layer includes an inductor structure including a first spiral-shaped region of the metal material and a second spiral-shaped region of the metal material proximate the first spiral-shaped region to provide an inductance between the first spiral-shaped region and the second spiral-shaped region, and forming, on the substrate, within the interconnect layer, a first via that electrically connects the first spiral-shaped region to a first region on the substrate and a second via that electrically connects the second spiral-shaped region to a second region on the substrate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

For example, many electrical circuits utilize inductors to filter signals in mixed signal devices and logic devices, such as embedded memories and radio frequency devices. However, existing inductor structures undesirably limit the design flexibility and component density.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of an example electrical circuit in accordance with various embodiments.

FIG. 2 is a top view of a semiconductor inductor structure suitable for use in the electrical circuit of FIG. 1 in accordance with various embodiments.

FIG. 3 is a cross-sectional view of the semiconductor inductor structure of FIG. 2 along the line 3-3 in FIG. 1.

FIGS. 4-5 are top views of alternative semiconductor inductor structures suitable for use in the electrical circuit of FIG. 1 in accordance with various embodiments.

FIGS. 6-16 are cross-sectional views of an example semiconductor inductor structure various phases of fabrication in accordance with various embodiments.

FIG. 17 is a flow chart of an example fabrication process for fabricating a semiconductor inductor structure in accordance with various embodiments.

FIG. 18 is a top view of an alternative semiconductor inductor structure in accordance with various embodiments.

FIG. 19 is a top view of an alternative semiconductor inductor structure in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

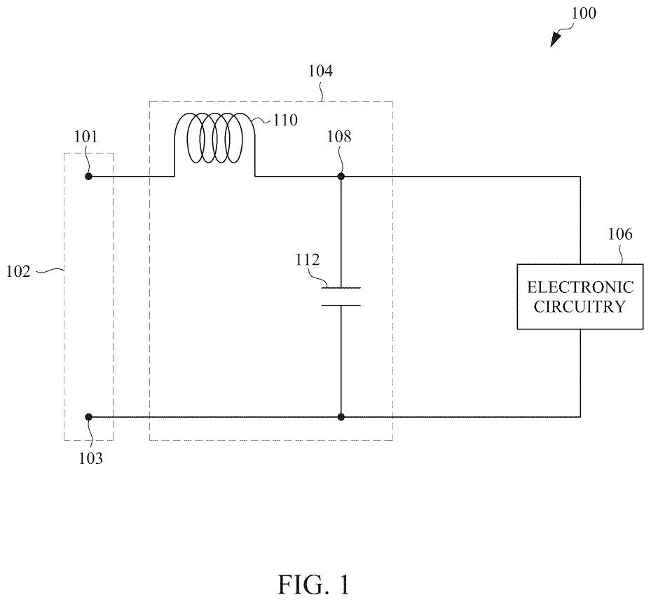

FIG. 1 depicts an exemplary embodiment of an electrical circuit 100 suitable for implementation in an integrated circuit or other semiconductor device package. The electrical circuit 100 includes an input interface 102 including respective input nodes 101, 103, which generally represent the pins, connectors, terminals, ports or other inputs associated with the electrical circuit 100 that are capable of being connected or otherwise coupled to a circuit board, wiring, or the like to establish an electrical connection between the electrical circuit 100 and an external device, component or system, such as a power source (e.g., a bus, a battery (or battery pack), and/or the like).

An input filtering arrangement 104 is coupled between the input interface 102 and electronic circuitry 106 associated with the electrical circuit 100. In this regard, the electronic circuitry 106 generally represent any type, configuration or combination of active or passive electronic components or systems suitably configured to provide a desired functionality for the electrical circuit 100. For example, the electronic circuitry 106 may include, but is not limited to one or more transistors, diodes, memory cells, resistors, capacitors, inductors, sensors, amplifiers, receivers, transmitters, microelectromechanical systems (MEMS) components, and/or the like. For example, the electronic circuitry 106 may include transistors, such as metal oxide semiconductor field effect transistors (MOSFETs), complementary metal oxide semiconductor (CMOS) transistors, bipolar junction transistors (BJT), high-voltage transistors, high-frequency transistors, p-channel field effect transistors (PFETs) and/or n-channel field effect transistors (NFETs) that are suitably configured to provide a desired functionality for the electrical circuit 100.

The illustrated input filtering arrangement 104 depicts an LC filter that includes an inductive element 110 (or inductor) that is connected electrically in series between an input node 101 of the input interface 102 and another node 108 connected to a respective input to the electronic circuitry 106 to provide a series inductance between the respective nodes 101, 108. The input filtering arrangement 104 also includes a capacitive element 112 (or capacitor) that is connected electrically between the respective input node 108 of the electronic circuitry 106 and the other input node 103 of the input interface 102 to provide a capacitance between the nodes 103, 108 electrically in parallel to the electronic circuitry 106. In this regard, the input filtering arrangement 104 may be configured as a low-pass filter to facilitate maintaining a substantially constant direct current (DC) voltage between the respective nodes 103, 108 coupled to the electronic circuitry 106. That said, it should be appreciated that the subject matter described herein is not limited to low-pass filters, and in alternative embodiments, the filtering arrangement 104 may be configured as a band-pass filter, a high-pass filter, or another suitable filter topology, the precise implementations details of which is not germane to the subject matter described herein. Additionally, the depiction in FIG. 1 is not limiting, and in practice, node 101 may be electrically connected to a different instance of electronic circuitry 106 to provide a series inductance between different circuits, as appropriate.

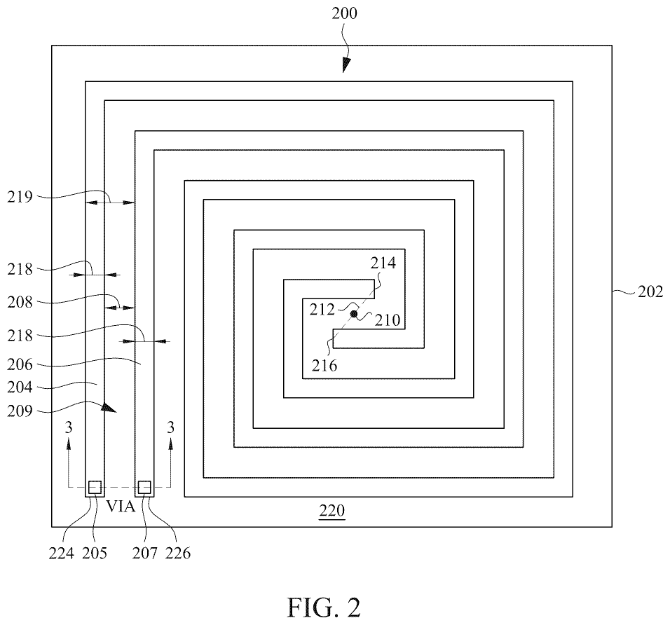

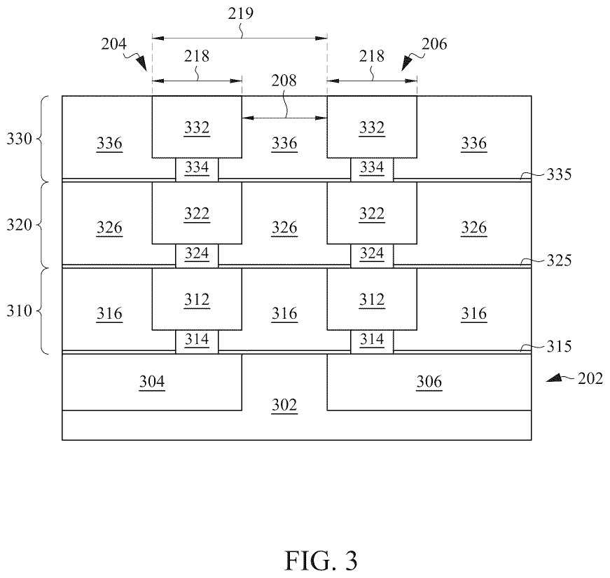

FIG. 2-3 depict an exemplary embodiment of an inductor structure 200 suitable for use as the inductor 110 in the electrical circuit 100 of FIG. 1. In this regard, FIG. 2 depicts a top view of a portion of an example semiconductor device that includes the inductor structure 200 fabricated on or overlying a portion of a semiconductor substrate 202, and FIG. 3 depicts a cross-sectional view of a portion of the inductor structure 200 along the line 3-3. In this regard, FIG. 3 depicts an embodiment corresponding to a multilayer inductor structure 200 that is fabricated within multiple vertical layers 310, 320, 330; however, it should be appreciated that in practice, the inductor structure 200 may be implemented as a single layer inductor structure within an individual layer. Moreover, it should be noted that for purposes of explanation, the subject matter may be described herein in the context of a multilayer inductor structure having substantially the same lateral geometry in common across the different vertical layers, while in other embodiments, the lateral geometry of a portion of multilayer inductor structure fabricated within a respective layer may be different from the lateral geometry of another portion of the multilayer inductor structure fabricated within an underlying or overlying vertical layer.

Referring to FIG. 2, the inductor structure 200 includes a first outer conductive structure 204 that is laterally spaced apart from a second inner conductive structure 206 by a lateral separation distance 208 occupied by an intervening portion 209 of insulating material 220 that provides lateral isolation between the respective conductive structures 204, 206 by virtue of the intervening portion 209 of the insulating material 220 occupying the lateral separation distance 208 between the conductive structures 204, 206. The lateral separation distance 208 is less than a maximum threshold separation distance to allow for a time-varying or alternating voltage differential between the respective conductive structures 204, 206 to induce an effective electrical current through the inductor structure 200 via electromagnetic induction, and in exemplary implementations, the lateral separation distance 208 is in the range of about 10 nanometers (nm) to about 25 nm. In practice, the lateral separation distance 208 may vary depending on the needs of the particular application to achieve the desired electrical performance and reliability.

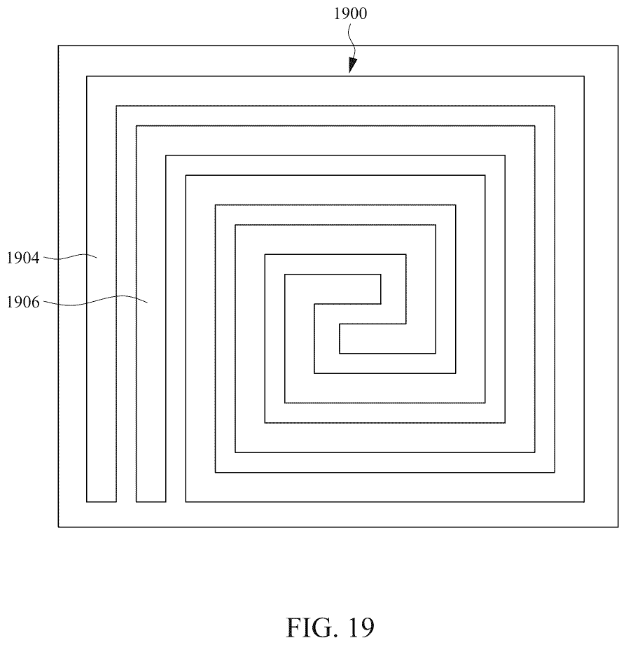

As described in greater detail below, in exemplary implementations, the respective conductive structures 204, 206 are defined and fabricated in concert with definition of the lateral separation distance 208 during back end of line (BEOL) process stages that allow for the respective lateral widths 218 of the respective conductive structures 204, 206 to be similarly reduced to be in the range of about 10 nm to about 25 nm substantially commensurate with the lateral separation distance 208. For example, the ratio of the lateral separation distance 208 to the lateral width 218 may be in the range of about 0.8 to about 1.5. This, in turn, allows for the pitch dimension 219 of the inductor structure 200 (i.e., the combination of the lateral width 218 and the separation distance 208) to be reduced to be in the range of about 20 nm to about 50 nm, which, in turn, allows for the density of the turns of the inductor structure 200 to be increased by accommodating a greater number of turns per unit of area. For example, in some implementations, the turns density of the inductor structure 200 may be increased by a factor on the order of 100 times greater, thereby achieving greater inductance per unit of area (where inductance is proportional to a square of the number of turns) and providing increased design flexibility by using inductor structures capable of higher inductor density or a broader range of potential inductor densities. In this regard, FIG. 2 depicts an embodiment where the outer conductive structure 204 includes 2.5 turns (e.g., two 360° loops plus one 180° loop) and the inner conductive structure 206 includes 2 turns, while FIG. 19 depicts an embodiment of an inductor structure 1900 where the outer conductive structure 1904 includes 3.5 turns and the inner conductive structure 1906 includes 3 turns for substantially the same unit of area, where inductance is proportional to the number of turns squared. It should be noted that although the subject matter is described herein in the context of the respective lateral widths 218 of the respective conductive structures 204, 206 being substantially equal to one another, in practice, the lateral widths of the conductive structures 204, 206 may be different from one another.

As depicted in FIG. 3, at least a connection portion of the first conductive structure 204 is formed on or overlying and in contact with a region 304 of conductive material formed in or on the semiconductor substrate 202 to provide an electrical connection between the first conductive structure 204 and the underlying conductive region 304 of the semiconductor substrate 202. Similarly, at least a connection portion of the second conductive structure 206 is formed on or overlying and in contact with a second region 306 of conductive material formed in or on the semiconductor substrate 202 to provide an electrical connection between the first conductive structure 204 and the second conductive region 306 of the semiconductor substrate 202, with the respective conductive regions 304, 306 being electrically isolated from one another by virtue of a region of insulating material 302 disposed laterally between the respective conductive regions 304, 306. For example, the insulating material 302 may be realized as a layer of an oxide material, where the conductive regions 304, 306 are realized as respective regions of a layer of a metal material or other conductive material formed in or on the layer of insulating material 302. In this regard, the first conductive region 304 may be realized as a metal line or trace configured to provide an electrical connection between the first conductive structure 204 and a respective input node 101 of an electrical circuit 100 fabricated on the semiconductor substrate 202, with the second conductive region 306 being realized as a metal line or trace configured to provide an electrical connection between the second conductive structure 206 and a different node 108 of the electrical circuit 100, such that the inductor structure 200 provides a series inductance between the respective nodes 101, 108 of the electrical circuit 100.

FIG. 2 depicts an exemplary lateral geometry where each of the conductive structures 204, 206 has a substantially spiral shape laterally within a respective layer on the semiconductor substrate 202. The spiral-shaped conductive structures 204, 206 are arranged in a nested or interlocking configuration, such that a respective portion of the other spiral-shaped conductive structure 204, 206 is laterally interposed between neighboring (or laterally adjacent) portions of a respective conductive structure 204, 206. In this regard, the respective spiral-shaped conductive structures 204, 206 are effectively concentric about a common point 210, which may be disposed or otherwise oriented at or near a geometric center of the inductor structure 200. For example, inner ends 214, 216 of the respective spiral-shaped conductive structures 204, 206 may be symmetrically disposed about and laterally offset from the center point 210 of the respective spirals by a substantially equivalent distance in opposite directions such that midpoints of the inner ends 214, 216 are coaxially aligned along an axis 212 through the center point 210 that intersects the midpoints of the inner ends 214, 216.

The lateral geometry of FIG. 2 corresponds to a rectangular or square spiral shape where the respective spiral-shaped conductive structures 204, 206 radiate outward from the inner ends 214, 216 by a sequence of linear segments that progressively increase in length and meet or intersect at substantially 90° angles, with parallel linear segments of a respective spiral-shaped conductive structures 204, 206 being laterally offset by a distance equal to twice the separation distance 208 between the spiral-shaped conductive structures 204, 206 plus a lateral width 218 of the intervening parallel portion of the other spiral-shaped conductive structure 204, 206. In this regard, in some implementations, the spiral-shaped conductive structures 204, 206 may be maintained substantially symmetrical to one another over a cumulative length equal to the length of the inner conductive structure 206 (e.g., the length of the conductive structure 206 from the inner end 216 to an outer end 226). Beyond the length of the inner conductive structure 206, the outer conductive structure 204 may include three additional linear segments that progressively increase in length to arrive at an outer end 224 of the outer conductive structure 204 that is laterally aligned substantially parallel with the outer end 226 of the inner conductive structure 206 such that an axis aligned with the respective outer ends 224, 226 is substantially perpendicular to the outer linear segments of the respective conductive structures 204, 206. Thus, the outer conductive structure 204 may be asymmetrical with respect to the inner conductive structure 206 so as to substantially circumscribe the inner conductive structure 206 within a respective layer on the semiconductor substrate 202.

Referring to FIG. 3 with continued reference to FIG. 2, in one or more embodiments, the inductor structure 200 is implemented as a multilayer inductor structure using one or more layers 310, 320, 330 formed on or overlying the semiconductor substrate 202. For example, in the exemplary embodiment depicted in FIG. 3, the inductor structure 200 maybe realized using three layers 310, 320, 330 formed on the semiconductor substrate 202, such as, for example, one or more metal interconnect layers formed during BEOL process stages. In this regard, the outer spiral-shaped conductive structure 204 may be realized as a corresponding spiral-shaped structure of a conductive metal material 312 of a first metal layer 310 that is patterned to provide the corresponding spiral-shaped structure within a layer of intermetal dielectric (IMD) material 316, and the inner spiral-shaped conductive structure 206 may be realized as a corresponding spiral-shaped structure of the conductive metal material 312 within the IMD material 316. As shown, the respective structures 204, 206 of conductive metal material 312 are electrically connected to the respective conductive regions 304, 306 on the underlying substrate 202 using respective portions of conductive via material 314 formed within respective connection regions 205, 207 of the layer of IMD material 316 and etch stop layer 315 at or near the outer ends 224, 226 of the spiral-shaped conductive structures 204, 206 that overlie the conductive regions 304, 306. In a similar manner, the spiral-shaped conductive structures 204, 206 may extend vertically through additional metal layers 320, 330 in a similar manner by forming the respective spiral-shaped structures 204, 206 in respective layers of metal material 322, 322 laterally separated from one another by intervening portions of respective layers of IMD material 326, 336 and respective etch stop layers 325, 335 and vertically connected to one another by respective portions of conductive via material 324, 334.

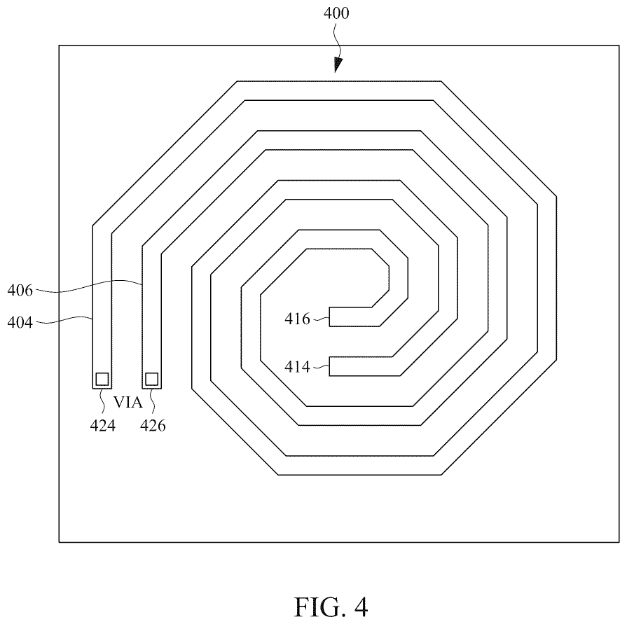

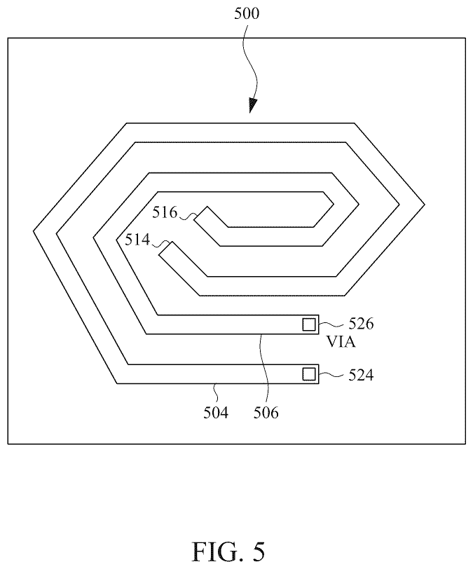

It should be noted that when the inductor structure 200 is implemented as a multilayer inductor structure as depicted in FIG. 3, the geometry or configuration of the respective intralayer lateral inductor structures formed within the respective metal interconnect layers 310, 320, 330 may vary from layer to layer with respect to one another. In this regard, the dimensions, orientation and/or shape of the respective intralayer lateral inductor structure formed in a lower metal interconnect layer 310 may be different from the respective intralayer lateral inductor structure formed in an overlying metal interconnect layer 320, 330. For example, FIGS. 4-5 depict alternative inductor structures 400, 500 suitable for implementation within one or more of the metal interconnect layers 310, 320, 330. In this regard, FIG. 4 depicts a spiral-shaped inductor structure 400 having an octangular or octagonal lateral geometry with an outer perimeter comprised of a sequence of substantially linear segments that meet or intersect at substantially 135° angles but progressively increase in length from the innermost segments to the outermost segments, such that the octagonal spiral-shaped conductive structures 404, 406 radiate outward octangularly from the inner ends 414, 416 to the outer ends 424, 426. In another example, FIG. 5 depicts a spiral-shaped inductor structure 500 having a hexagonal lateral geometry with an outer perimeter comprised of a sequence of linear segments that meet or intersect at substantially 120° angles and progressively increase in length from the innermost segments to the outermost segments, such that the hexagonal spiral-shaped conductive structures 504, 506 radiate outward hexagonally from the inner ends 514, 516 to the outer ends 524, 526. It should be noted that different shapes of the inductor structures 200, 400, 500 offer design flexibility, and the subject matter described herein is not necessarily limited to a particular shape for the inductor structure.

It should be appreciated that the subject matter described herein is not necessarily limited to spiral-shaped inductor structures having rectangular (e.g., inductor structure 200), pentagonal, hexagonal (e.g., inductor structure 500), octagonal (e.g., inductor structure 400) or other geometric arrangements, and may be implemented in an equivalent manner using any sort of oblong, elliptical, clothoid or other suitable spiral geometry. Moreover, the subject matter described herein is not necessarily limited to any particular combination or configuration of the inductor structures. For example, in some implementations, a multilayer inductor structure may include a combination of one or more rectangular spiral-shaped lateral inductor structures 200, one or more hexagonal spiral-shaped lateral inductor structures 500, and/or one or more octangular spiral-shaped lateral inductor structures 400, while in other implementations, a multilayer inductor structure may include a substantially identical spiral-shaped lateral inductor structures for each of the respective layers utilized for the multilayer inductor structure.

In addition to varying the lateral geometry or configuration of the spiral-shaped inductor structure within a respective lateral layer to achieve a corresponding increase or decrease in the total inductance (or inductance per unit area) associated with the respective spiral-shaped inductor structure by altering the number of turns per unit area. Additionally, in practice, the lateral separation distance 208 between the respective spiral-shaped conductive structures 204, 206 and/or the lateral width 218 of the respective spiral-shaped conductive structures 204, 206 may be varied within a respective lateral layer to achieve a corresponding increase or decrease in the total inductance (or inductance per unit area). In this regard, decreasing the lateral separation distance 208 may increase the inductance density associated with the particular spiral-shaped inductor structure by increasing the electromagnetic interference or coupling between spiral-shaped conductive structures 204, 206 to increase the inductance while also reducing the total lateral area required for the respective lateral inductor structure. Accordingly, the subject matter described herein is not limited to any particular dimensions or other geometric configurations for the spiral-shaped inductor structure, as a circuit designer may vary the lateral geometry and pitch dimension of a spiral-shaped inductor structure to achieve a desired inductance (or a desired inductor density) for a particular application given an amount of available area on the substrate for fabrication.

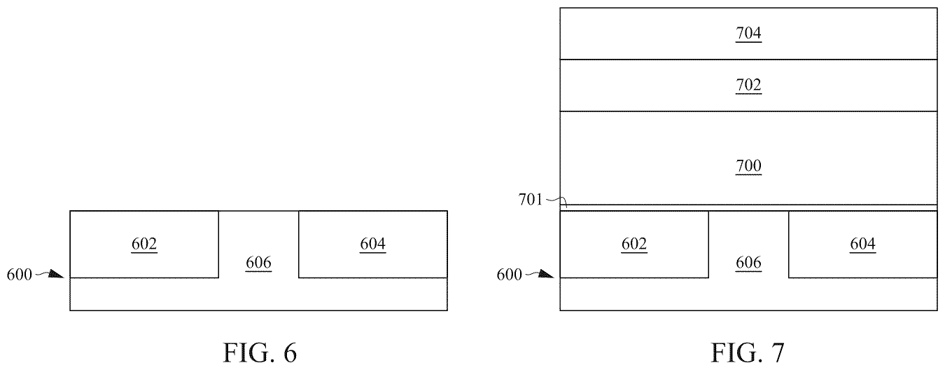

FIGS. 6-16 illustrate, in cross-section, one or more methods for fabricating an inductor structure 1400 suitable for use as a spiral-shaped inductor structure (e.g., one of the structures 200, 400, 500) in a metal interconnect layer 1410 using a self-aligned double-patterning process during an integrated circuit manufacturing process in accordance with exemplary embodiments. Various steps in the manufacture of semiconductor devices are well known and so, in the interest of brevity, many conventional steps will only be mentioned briefly herein or will be omitted entirely without providing the well-known process details. In this regard, in exemplary implementations, the inductor structure 1400 is fabricated during one or more BEOL process stages after transistors or other electronic circuitry (e.g., electronic circuitry 106) have been fabricated on a semiconductor substrate. For example, the inductor structure 1400 may be formed during or concurrent to fabrication of one or more metal interconnect layers, for example, as part of a self-aligned double patterning process stage.

FIG. 6 depicts a stage of an integrated circuit manufacturing process after fabrication of a semiconductor substrate 600 that includes respective regions 602, 604 of conductive metal material that are fabricated within a layer of dielectric material 606, such as silicon dioxide or another oxide material suitable for use as an intermetal dielectric providing electrical isolation laterally between the respective metal regions 602, 604. The conductive regions 602, 604 generally corresponding to the routing, traces or other electrical connections to/from the respective terminals of the inductor structure 1400 (e.g., nodes 101 and 108 of inductor 110) that are fabricated within a metal interconnect layer comprising an intermetal dielectric material 606. For example, one of the regions 602, 604 may be electrically connected to a source, a drain, or a gate electrode of one or more transistors fabricated on or within underlying semiconductor material of the substrate, while the other region 602, 604 may be electrically connected to an input and/or output node an electrical circuit 100 fabricated on the substrate or a source, a drain, or a gate electrode of a different transistor fabricated on or within underlying semiconductor material of the substrate, such that the inductor structure fabricated on the substrate effectively provides a series inductance between the metal regions 602, 604.

As illustrated in FIG. 7, the integrated circuit manufacturing process continues by forming an etch stop layer 701 overlying the semiconductor substrate and forming a layer of an intermetal dielectric (IMD) material 700 overlying the semiconductor substrate. For example, the IMD material 700 may be realized as silicon dioxide or another suitable dielectric material conformally deposited on or overlying upper surface of the semiconductor substrate 600 to a thickness in the range of about 40 nm to about 70 nm. After forming the layer of IMD material 700, the integrated circuit manufacturing process continues by forming a layer of a hard mask material 702 overlying the layer of IMD material 700, for example, by conformally depositing a layer of silicon nitride material on or overlying upper surface of the layer of IMD material 700 to a thickness in the range of about 100 Å to about 500 Å. Thereafter, the fabrication process continues by forming another layer of masking material 704 overlying the layer of hard mask material 702, for example, by conformally depositing a layer of silicon oxide material on or overlying upper surface of the layer of hard mask material 702 to a thickness in the range of about 300 Å to about 700 Å. The etch stop layer 701 has a different etch selectivity than IMD material 700 to provide a mechanism for stopping the etch process when forming contacts, vias, or other structures within the IMD material 700. The etch stop layer 701 may comprise or may be aluminum nitride, silicon carbonitride, silicon oxycarbide, carbon nitride, the like, or combinations thereof. The etch stop layer 701 may be deposited by a plasma-assisted chemical vapor deposition process, a high-density plasma chemical vapor deposition process, an atomic layer deposition process, or other suitable deposition process.

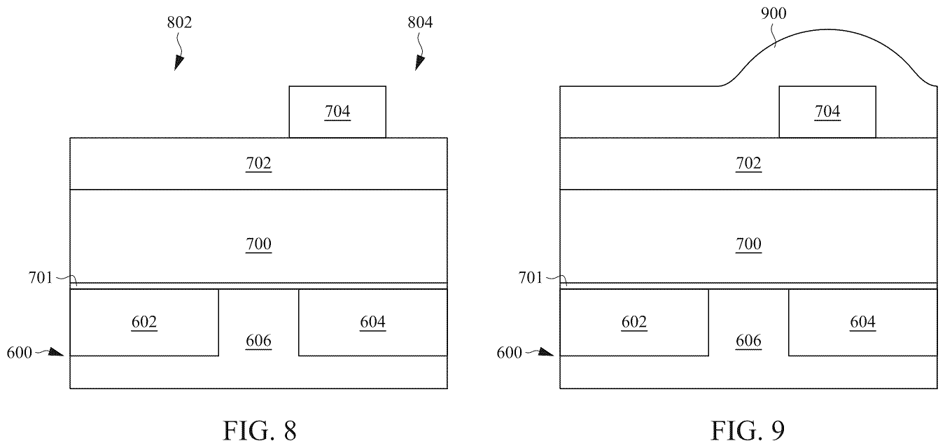

Referring now to FIG. 8, the fabrication process continues by patterning and anisotropically (or directionally) etching the layer of masking material 704 using suitable photolithography and etching techniques as part of a self-aligned double-patterning process to define voided regions 802, 804 within the masking material 704 for a first region of conductive metal material that is physically distinct from one or more other regions of conductive metal material within the respective metal interconnect layer. For purposes of fabricating an inductor structure, the masking material 704 is patterned and etched to define voided regions 802, 804 within the masking material 704 overlying the respective metal regions 602, 604 corresponding to a respective one of the spiral-shaped conductive structures (e.g., outer conductive structure 204, 404, 504) and the intervening portion of IMD material 700 (e.g., intervening portion 209), while the remaining portions of the masking material 704 define the respective lateral location and configuration of the other spiral-shaped conductive structure (e.g., inner conductive structure 206, 406, 506). In this regard, the voided regions 802, 804 are utilized to define lateral boundaries and respective lateral locations for subsequently formed spacers that define the respective lateral separation distance 1408 and lateral width 1418 for outer spiral-shaped conductive structure 1404 of the resulting inductor structure 1400, while the remaining portion of the IMD material 700 defines the respective lateral location and lateral width of the inner spiral-shaped conductive structure 1406, as described in greater detail below.

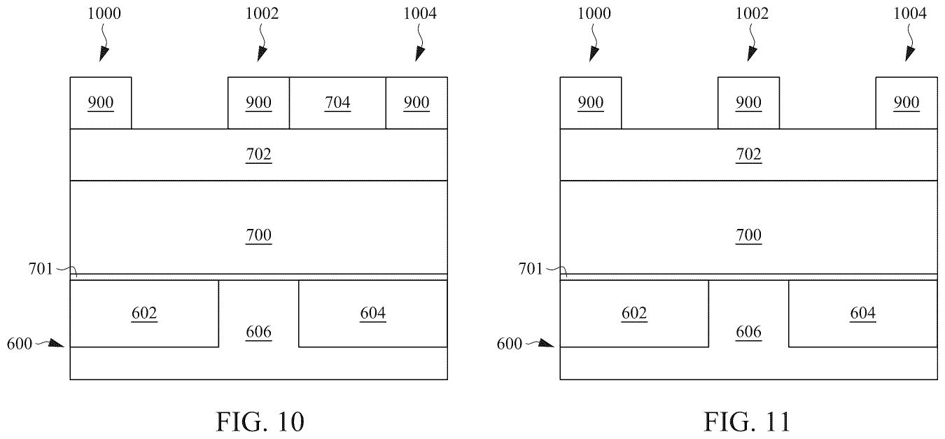

As part of the self-aligned double-patterning process, after forming voided regions 802, 804 within the layer of masking material 704, the fabrication process continues by forming a layer of spacer material 900 overlying the semiconductor substrate as shown in FIG. 9. For example, the layer of spacer material 900 may be formed by conformally depositing a layer of oxide material on and overlying the upper surface of the hard mask material 702 to a thickness in the range of about 60 Å to about 200 Å. After forming the layer of spacer material 900, the fabrication process continues by anisotropically (or directionally) etching the layer of spacer material 900 to remove the spacer material 900 from planar surfaces to form respective sets of spacers 1000, 1002, 1004 that are self-aligned with respect to the interior sidewalls of the voided regions 802, 804, as depicted in FIG. 10. In this regard, the use of self-aligned spacers 1000, 1002, 1004 for subsequent masking allows for the respective lateral widths 1418 of the conductive structures 1404, 1406 to be reduced and/or the lateral separation distance 1408 to be reduced using smaller pitch dimensions and higher aspect ratio conductive structures 1404, 1406 than could otherwise be formed by relying solely on the layer of masking material 704 and/or the hard mask material 702. Accordingly, in some implementations, the layer of spacer material 900 may be formed to a thickness that corresponds to the desired lateral separation distance 1408 between the spiral-shaped conductive structures 1404, 1406 and/or the desired lateral width 1418 of the spiral-shaped conductive structures 1404, 1406. That said, in other implementations, the thickness of the layer of spacer material 900 may be constrained by other electrical circuitry or interconnections to be fabricated on the semiconductor substrate, in which case, the lateral separation distance 1408 and/or lateral width 1418 is controlled by the definition of the voided regions 802, 804. In practice, the layer of spacer material 900 and the underlying masking material 704 are anisotropically etched to a distance or depth greater than or equal to the thickness of the spacer material 900 to remove portions of the spacer material 900 from the substantially planar surfaces of the semiconductor substrate, resulting in spacers 1000, 1002, 1004 that define the spiral-shaped conductive structures 1404, 1406 and the lateral separation distance 1408.

Referring to FIG. 11, as part of the self-aligned double-patterning process, after removing portions of the spacer material 900 from the substantially planar surfaces to define the spacers 1000, 1002, 1004, remaining portions of the masking material 704 are removed using suitable photolithography and etching techniques to define respective lateral locations and lateral widths (or boundaries) for another region of conductive metal material to be fabricated within the respective metal interconnect layer that is physically distinct from regions defined using voided regions 802, 804. In this regard, the remaining portions of masking material 704 may be removed concurrently define routing, traces or other regions of metal material within the respective interconnect layer on other areas of the semiconductor substrate 600, resulting in the state of the semiconductor substrate depicted in FIG. 11.

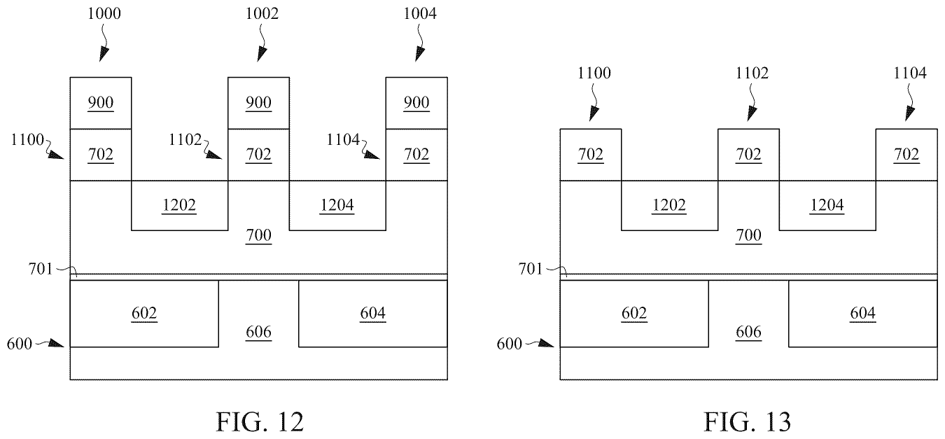

Referring to FIG. 12, after forming the spacers 1000, 1002, 1004, the fabrication process continues by anisotropically etching the hard mask material 702 using the spacers 1000, 1002, 1004 as an etch mask to define corresponding self-aligned spacer regions 1100, 1102, 1104 of the hard mask material 702 underlying the spacers 1000, 1002, 1004.

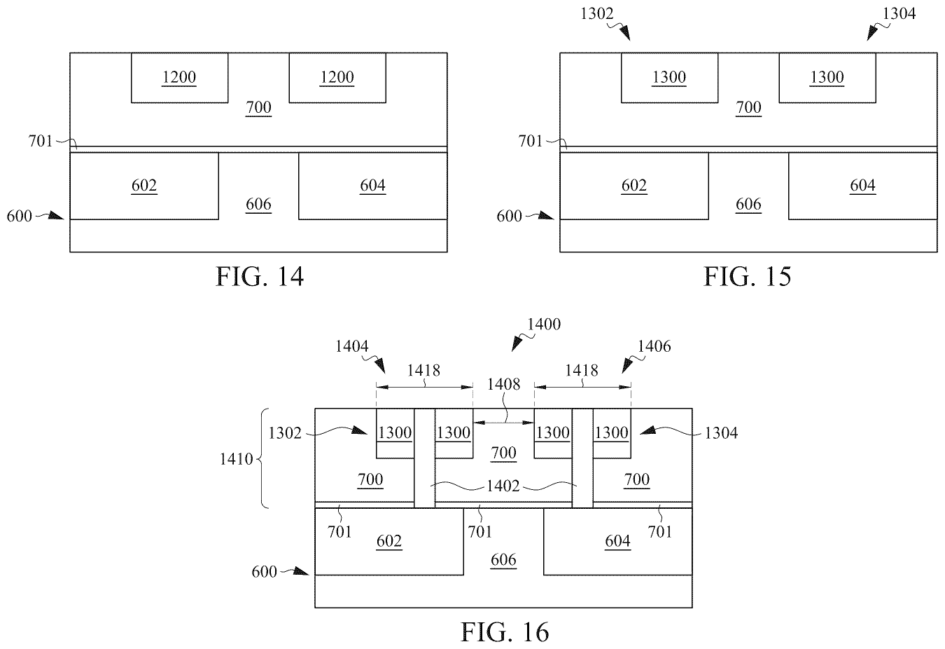

As illustrated in FIG. 13, after forming spacer regions 1100, 1102, 1104 of hard mask material 702, the fabrication process continues by anisotropically etching the layer of IMD material 700 using the hard mask spacers 1100, 1102, 1104 as an etch mask to form voided regions 1202, 1204 within the layer of IMD material 700 corresponding to the respective conductive structures 1404, 1406 of the inductor structure 1400. In this regard, the layer of IMD material 700 may be anisotropically etched to a depth that is greater than or equal to a thickness of the remaining spacer material 900 of the spacers 1000, 1002, 1004 to remove the spacer material 900 from the upper surface of the hard mask spacers 1100, 1102, 1104 concurrent to forming the voided regions 1202, 1204. After forming the voided regions 1202, 1204, the remaining portions of hard mask material 702 may be removed from the upper surface of the semiconductor substrate 600 in a conventional manner as depicted in FIG. 14.

Referring to FIG. 15 with continued reference to FIGS. 13-14, in exemplary implementations, the inductor structure 1400 is formed as part of a metal first, via last processing stage, where the layer of IMD material 700 is etched to a depth that is less than a thickness of the layer of IMD material 700 such that portions of the IMD material 700 remain vertically between the bottom surface of the voided regions 1202, 1204 and the underlying metal regions 602, 604. For example, in exemplary implementations, the IMD material 700 is etched to form voided regions 1202, 1204 having a depth (and a corresponding height or vertical dimension of the conductive structures 1404, 1406) in the range of about 20 nm to about 35 nm. After forming voided regions 1202, 1204 within the layer of IMD material 700 and removing the hard mask spacers 1100, 1102, 1104, the fabrication process continues by forming respective regions 1302, 1304 of metal material 1300 for the respective conductive structures 1404, 1406 of the inductor structure 200 in the voided regions 1202, 1204. For example, a layer of metal material 1300 may be conformally deposited on or overlying the upper surface of the semiconductor substrate to a thickness that is greater than or equal to a depth of the voided regions 1202, 1204 (e.g., a flush fill or slight overfill) before planarizing the upper surface of the semiconductor substrate, resulting in the state depicted in FIG. 15.

Referring to FIG. 16, after forming the layer of metal material 1300, as part of a metal first, via last processing stage, fabrication of a respective layer of the inductor structure 1400 may be completed by forming conductive vias 1402 within the respective regions 1302, 1304 of metal material 1300 that provide an electrical connection between the respective metal regions 1302, 1304 of the respective conductive structures 1404, 1406 of the inductor structure 1400 and the underlying metal interconnection regions 602, 604. In this regard, conductive vias 1402 may be fabricated through the respective layer of metal material 1300 in a conventional manner which is not germane to this disclosure, for example, by patterning and etching corresponding voided regions within the respective metal regions 1302, 1304 and then forming conductive via material within the voids (e.g., depositing or otherwise forming a layer of metal material on or overlying the semiconductor substrate) before planarizing the upper surface of the semiconductor substrate to arrive at the state of the semiconductor substrate depicted in FIG. 16.

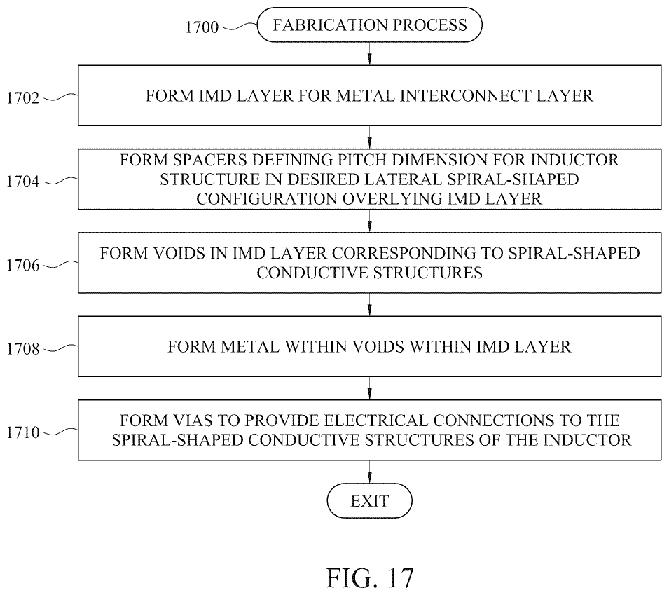

FIG. 17 depicts an exemplary embodiment of a fabrication process 1700 suitable for use to fabricate spiral-shaped conductive structures with reduced pitch dimensions within a metal interconnect layer as part of one or more BEOL process stages for greater turns density and greater inductance density. The fabrication process 1700 begins at 1702 by forming a layer of intermetal dielectric material on or overlying a semiconductor substrate, as depicted in FIG. 7.

The fabrication process 1700 continues at 1704 by forming spacers overlying the layer of IMD material using the self-aligned double-patterning process described above (e.g., FIGS. 8-12). The spacers define the pitch dimensions and corresponding lateral widths and separation distances for the inductor structure to be formed in the desired lateral spiral-shaped geometric configuration, such as any one of the spiral-shaped configurations depicted in any one of FIGS. 2, 4 and 5.

At 1706, the fabrication process 1700 continues by forming voids corresponding to the desired spiral-shaped conductive structures within the IMD layer as depicted in FIG. 13 prior to forming metal or another suitable conductive material for the spiral-shaped conductive structures within the voids within the IMD layer at step 1708 as depicted in FIG. 15.

At 1710, the fabrication process 1700 continues by forming conductive vias that provide electrical connections to/from the spiral-shaped conductive structures of the inductor. For example, as depicted in FIG. 16, in some implementations, conductive vias 1402 may be formed within the spiral-shaped conductive structures and through the layer of IMD material 700 to contact underlying regions 604, 606 on the semiconductor substrate. As described above in the context of FIG. 1, each of the regions 604, 606 generally corresponds to a respective node 101, 108 of the inductor structure 1400 that may be electrically connected to other electronic circuitry 106 or a respective input or output terminal. For example, in some implementations, each of the regions 604, 606 may be electrically connected to different electrical circuits such that the inductor structure 1400 provides a series inductance between different circuits.

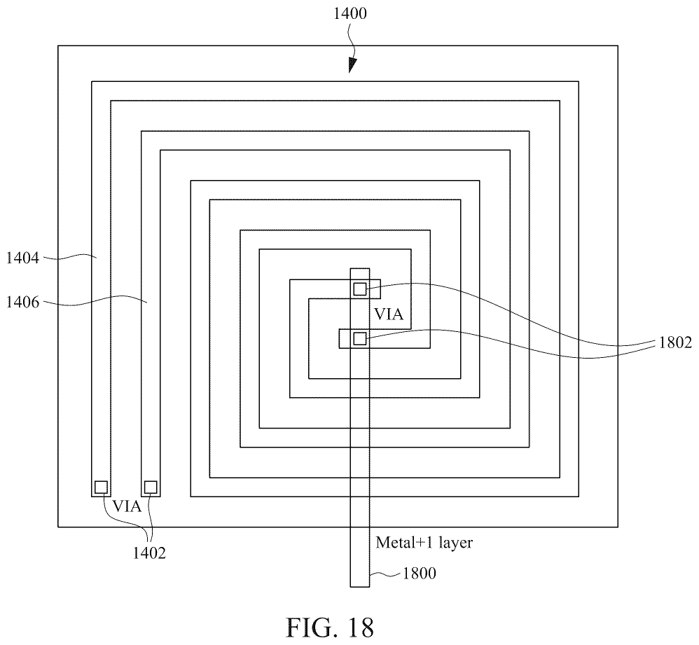

In alternative implementations, the vias may be formed in an overlying layer to establish an electrical connection to an upper layer on the semiconductor substrate. For example, FIG. 18 depicts an implementation where in addition to the vias 1802 connecting the spiral-shaped inductor structure 1400 to underlying regions 604, 606 at or near the outer ends of the spiral-shaped conductive structures 1404, 1406, an additional set of vias 1802 are formed. Vias 1802 are formed at or near the inner ends of the spiral-shaped conductive structures 1404, 1406 within an overlying metal interconnect layer that provides an electrical connection to a corresponding region 1800 of metal or other conductive material within the overlying metal interconnect layer that provides the desired electrical connection to the inductor structure 1400.

By virtue of the subject matter described herein, the lateral separation distance between spiral-shaped conductive structures may be reduced using spacers as part of a self-aligned double-patterning process to increase the number of turns per unit area and correspondingly increase the inductance density using a spiral-shaped inductor structure.

In one aspect, a semiconductor device is provided that includes a transistor comprising a source, drain, and gate on a substrate and an inductor structure on the substrate, the inductor structure comprising a first spiral-shaped conductive structure and a second spiral-shaped conductive structure proximate the first spiral-shaped conductive structure to provide an inductance between the first spiral-shaped conductive structure and the second spiral-shaped conductive structure, wherein one of the first spiral-shaped conductive structure and the second spiral-shaped conductive structure is electrically connected to at least one of the source, drain, and gate of the transistor.

In one aspect of the semiconductor device, at least a portion of the second spiral-shaped conductive structure is laterally interposed between neighboring portions of the first spiral-shaped conductive structure aligned substantially parallel to the portion of the second spiral-shaped conductive structure.

In one aspect of the semiconductor device, the first spiral-shaped conductive structure and the second spiral-shaped conductive structure have an interlocking configuration.

In one aspect of the semiconductor device, the first spiral-shaped conductive structure and the second spiral-shaped conductive structure are concentric about a common point.

In one aspect of the semiconductor device, inner ends of the first spiral-shaped conductive structure and the second spiral-shaped conductive structure are symmetrically disposed about the common point in opposite directions.

In one aspect of the semiconductor device, inner ends of the first spiral-shaped conductive structure and the second spiral-shaped conductive structure are coaxially aligned along an axis through the common point that intersects the inner ends of the first spiral-shaped conductive structure and the second spiral-shaped conductive structure.

In one aspect of the semiconductor device, the inductor structure comprises a multilayer structure fabricated in a first metal interconnect layer and a second metal interconnect layer.

In one aspect of the semiconductor device, the first metal interconnect layer comprises the first spiral-shaped conductive structure of a first metal material of the first metal interconnect layer and the second spiral-shaped conductive structure of the first metal material of the first metal interconnect layer spaced apart by a lateral distance of a first intermetal dielectric material of the first metal interconnect layer.

In one aspect of the semiconductor device, the second metal interconnect layer comprises a third spiral-shaped conductive structure of a second metal material of the second metal interconnect layer and a fourth spiral-shaped conductive structure of the second metal material of the second metal interconnect layer spaced apart by a second lateral distance of a second intermetal dielectric material of the second metal interconnect layer, wherein the third spiral-shaped conductive structure is electrically connected to the first spiral-shaped conductive structure and the fourth spiral-shaped conductive structure is electrically connected to the second spiral-shaped conductive structure.

In one aspect of the semiconductor device, a first geometry of the first spiral-shaped conductive structure is different from a third geometry of the third spiral-shaped conductive structure.

In one aspect of the semiconductor device, at least a portion of the first spiral-shaped conductive structure is symmetrical to the second spiral-shaped conductive structure.

In one aspect, a fabrication method is provided. The fabrication method involves forming, on a substrate, a transistor comprising a source, drain, and gate, forming, on the substrate, an interconnect layer configured to provide electrical connections for the source, drain, and gate, the interconnect layer comprising regions of metal material disposed within a layer of dielectric material, wherein the interconnect layer comprises an inductor structure including a first spiral-shaped region of the metal material and a second spiral-shaped region of the metal material proximate the first spiral-shaped region to provide an inductance between the first spiral-shaped region and the second spiral-shaped region, and forming, on the substrate, a plurality of vias within the interconnect layer, wherein a first via of the plurality of vias electrically connects the first spiral-shaped region to a first region on the substrate underlying the first via and a second via of the plurality of vias electrically connects the second spiral-shaped region to a second region on the substrate underlying the second via.

In one aspect of the fabrication method, at least one of the first region and the second region is configured to provide an electrical connection to at least one of the source, drain and gate of the transistor.

In one aspect of the fabrication method, forming the interconnect layer comprises forming the layer of dielectric material on the substrate, forming one or more spacers overlying the layer of dielectric material to define a first spiral-shaped voided region and a second spiral-shaped voided region in the layer of dielectric material, etching the layer of dielectric material using the one or more spacers to form the first spiral-shaped voided region and the second spiral-shaped voided region in the layer of dielectric material, and forming the first spiral-shaped region and the second spiral-shaped region of the metal material within the first spiral-shaped voided region and the second spiral-shaped voided region in the layer of dielectric material.

In one aspect of the fabrication method, forming the one or more spacers comprises forming a layer of spacer material having a thickness corresponding to a lateral distance associated with intervening portions of the layer of dielectric material between the first spiral-shaped region and the second spiral-shaped region of the metal material.

In one aspect of the fabrication method, forming the interconnect layer comprises forming at least a portion of the second spiral-shaped region aligned substantially parallel to neighboring portions of the first spiral-shaped region, wherein respective intervening portions of the layer of dielectric material are interposed between the portion of the second spiral-shaped region and a respective neighboring portion of the first spiral-shaped region.

In one aspect of the fabrication method, forming the interconnect layer comprises forming the first spiral-shaped region and the second spiral-shaped region concentric about a common point.

In another aspect, a semiconductor inductor structure is provided that includes a first spiral-shaped structure of a conductive material within an interconnect layer comprising the conductive material disposed within a layer of dielectric material overlying a semiconductor substrate, a second spiral-shaped structure of the conductive material within the interconnect layer overlying the semiconductor substrate, wherein a portion of the second spiral-shaped structure is aligned substantially parallel to neighboring portions of the first spiral-shaped structure, one or more intervening portions of the layer of dielectric material disposed between the portion of the second spiral-shaped structure and a respective neighboring portion of the first spiral-shaped structure, a first via within the interconnect layer between the first spiral-shaped structure and a first conductive region on the semiconductor substrate, and a second via within the interconnect layer between the second spiral-shaped structure and a second conductive region on the semiconductor substrate.

In one aspect, the semiconductor inductor structure further includes a second interconnect layer overlying the interconnect layer, wherein the second interconnect layer includes a third via overlying a first inner end of the first spiral-shaped structure, a fourth via overlying a second inner end of the second spiral-shaped structure, and a conductive material between the third via and the fourth via within the interconnect layer to provide an electrical connection between the first spiral-shaped structure and the second spiral-shaped structure within the second interconnect layer.

In one aspect, the semiconductor inductor structure further includes a second interconnect layer overlying the interconnect layer, wherein the second interconnect layer includes a third spiral-shaped structure of the conductive material within the second interconnect layer, a fourth spiral-shaped structure of the conductive material within the second interconnect layer, a third via within the second interconnect layer between the first spiral-shaped structure and the third spiral-shaped structure, and a fourth via within the second interconnect layer between the second spiral-shaped structure and the fourth spiral-shaped structure.

In one aspect, a lateral geometry of the third spiral-shaped structure is different from a lateral geometry of the first spiral-shaped structure and a lateral geometry of the fourth spiral-shaped structure is different from a lateral geometry of the second spiral-shaped structure.

In another aspect, the third spiral-shaped structure and the first spiral-shaped structure have a common lateral geometry and fourth spiral-shaped structure and the second spiral-shaped structure have a common lateral geometry.

In one aspect of the semiconductor inductor structure, inner ends of the first spiral-shaped structure and the second spiral-shaped structure are symmetrically disposed about a common point in opposite directions.

In one aspect of the semiconductor inductor structure, at least a portion of the first spiral-shaped structure is symmetrical to the second spiral-shaped structure in an interlocking configuration spaced apart by the one or more intervening portions of the layer of dielectric material.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor device, comprising:
a transistor comprising a source, drain, and gate on a substrate; and
an inductor structure (1400) on the substrate, the inductor structure (1400) comprising a first spiral-shaped conductive structure (204) and a second spiral-shaped conductive structure (204) proximate the first spiral-shaped conductive structure (204) to provide an inductance between the first spiral-shaped conductive structure (204) and the second spiral-shaped conductive structure (204), wherein one of the first spiral-shaped conductive structure (204) and the second spiral-shaped conductive structure (204) is electrically connected to at least one of the source, drain, and gate of the transistor, wherein at least a portion of the second spiral-shaped conductive structure (204) is laterally interposed between neighboring portions of the first spiral-shaped conductive structure (204) aligned substantially parallel to the portion of the second spiral-shaped conductive structure (204).

2. The semiconductor device of claim 1, wherein the first spiral-shaped conductive structure (204) and the second spiral-shaped conductive structure (204) have an interlocking configuration.

3. The semiconductor device of claim 1, wherein the first spiral-shaped conductive structure (204) and the second spiral-shaped conductive structure (204) are concentric about a common point (210).

4. The semiconductor device of claim 3, wherein inner ends (214) of the first spiral-shaped conductive structure (204) and the second spiral-shaped conductive structure (204) are symmetrically disposed about the common point (210) in opposite directions.

5. The semiconductor device of claim 3, wherein inner ends (214) of the first spiral-shaped conductive structure (204) and the second spiral-shaped conductive structure (204) are coaxially aligned along an axis (212) through the common point (210) that intersects the inner ends (214) of the first spiral-shaped conductive structure (204) and the second spiral-shaped conductive structure (204).

6. The semiconductor device of claim 1, wherein the inductor structure (1400) comprises a multilayer structure fabricated in a first metal interconnect layer and a second metal interconnect layer.

7. The semiconductor device of claim 6, wherein:
the first metal interconnect layer comprises the first spiral-shaped conductive structure (204) of a first metal material (1300) of the first metal interconnect layer and the second spiral-shaped conductive structure (204) of the first metal material (1300) of the first metal interconnect layer spaced apart by a lateral distance of a first intermetal dielectric material (606) of the first metal interconnect layer;
the second metal interconnect layer comprises a third spiral-shaped conductive structure (204) of a second metal material (1300) of the second metal interconnect layer and a fourth spiral-shaped conductive structure (204) of the second metal material (1300) of the second metal interconnect layer spaced apart by a second lateral distance of a second intermetal dielectric material (606) of the second metal interconnect layer, wherein the third spiral-shaped conductive structure (204) is electrically connected to the first spiral-shaped conductive structure (204) and the fourth spiral-shaped conductive structure (204) is electrically connected to the second spiral-shaped conductive structure (204); and
a first geometry of the first spiral-shaped conductive structure (204) is different from a third geometry of the third spiral-shaped conductive structure (204).

8. A fabrication method, comprising:
forming, on a substrate, a transistor comprising a source, drain, and gate;
forming, on the substrate, an interconnect layer configured to provide electrical connections for the source, drain, and gate, the interconnect layer comprising regions (1302) of metal material (1300) disposed within a layer of dielectric material (606), wherein the interconnect layer comprises an inductor structure (1400) including a first spiral-shaped region (1800) of the metal material (1300) and a second spiral-shaped region (1800) of the metal material (1300) proximate the first spiral-shaped region (1800) to provide an inductance between the first spiral-shaped region (1800) and the second spiral-shaped region (1800); and
forming, on the substrate, a plurality of vias (1802) within the interconnect layer, wherein a first via of the plurality of vias (1802) electrically connects the first spiral-shaped region (1800) to a first region (1800) on the substrate underlying the first via and a second via of the plurality of vias (1802) electrically connects the second spiral-shaped region (1800) to a second region (306) on the substrate underlying the second via.

9. The fabrication method of claim 8, wherein at least one of the first region (1800) and the second region (306) is configured to provide an electrical connection to at least one of the source, drain and gate of the transistor.

10. The fabrication method of claim 8, wherein forming the interconnect layer comprises:
forming the layer of dielectric material (606) on the substrate;
forming one or more spacers (1000) overlying the layer of dielectric material (606) to define a first spiral-shaped voided region (1800) and a second spiral-shaped voided region (1800) in the layer of dielectric material (606);
etching the layer of dielectric material (606) using the one or more spacers (1000) to form the first spiral-shaped voided region (1800) and the second spiral-shaped voided region (1800) in the layer of dielectric material (606); and
forming the first spiral-shaped region (1800) and the second spiral-shaped region (1800) of the metal material (1300) within the first spiral-shaped voided region (1800) and the second spiral-shaped voided region (1800) in the layer of dielectric material (606).

11. The fabrication method of claim 10, wherein forming the one or more spacers (1000) comprises forming a layer of spacer material (900) having a thickness corresponding to a lateral distance associated with intervening portions of the layer of dielectric material (606) between the first spiral-shaped region (1800) and the second spiral-shaped region (1800) of the metal material (1300).

12. The fabrication method of claim 8, wherein forming the interconnect layer comprises forming at least a portion of the second spiral-shaped region (1800) aligned substantially parallel to neighboring portions of the first spiral-shaped region (1800), wherein respective intervening portions of the layer of dielectric material (606) are interposed between the portion of the second spiral-shaped region (1800) and a respective neighboring portion of the first spiral-shaped region (1800).

13. The fabrication method of claim 8, wherein forming the interconnect layer comprises forming the first spiral-shaped region (1800) and the second spiral-shaped region (1800) concentric about a common point (210).

14. A semiconductor inductor structure (1400) comprising:
a first spiral-shaped structure of a conductive material (314) within an interconnect layer comprising the conductive material (314) disposed within a layer of dielectric material (606) overlying a semiconductor substrate (202);
a second spiral-shaped structure of the conductive material (314) within the interconnect layer overlying the semiconductor substrate (202), wherein a portion of the second spiral-shaped structure is aligned substantially parallel to neighboring portions of the first spiral-shaped structure;
one or more intervening portions of the layer of dielectric material (606) disposed between the portion of the second spiral-shaped structure and a respective neighboring portion of the first spiral-shaped structure;
a first via within the interconnect layer between the first spiral-shaped structure and a first conductive region (304) on the semiconductor substrate (202); and
a second via within the interconnect layer between the second spiral-shaped structure and a second conductive region (306) on the semiconductor substrate (202).

15. The semiconductor inductor structure (1400) of claim 14, further comprising a second interconnect layer overlying the interconnect layer, wherein the second interconnect layer comprises:
a third via overlying a first inner end (216) of the first spiral-shaped structure;
a fourth via overlying a second inner end (216) of the second spiral-shaped structure; and
a conductive material (314) between the third via and the fourth via within the interconnect layer to provide an electrical connection between the first spiral-shaped structure and the second spiral-shaped structure within the second interconnect layer.

16. The semiconductor inductor structure (1400) of claim 14, further comprising a second interconnect layer overlying the interconnect layer, wherein the second interconnect layer comprises:
a third spiral-shaped structure of the conductive material (314) within the second interconnect layer;
a fourth spiral-shaped structure of the conductive material (314) within the second interconnect layer;
a third via within the second interconnect layer between the first spiral-shaped structure and the third spiral-shaped structure; and
a fourth via within the second interconnect layer between the second spiral-shaped structure and the fourth spiral-shaped structure.

17. The semiconductor inductor structure (1400) of claim 16, wherein a lateral geometry of the third spiral-shaped structure is different from a lateral geometry of the first spiral-shaped structure.

18. The semiconductor inductor structure (1400) of claim 16, wherein the third spiral-shaped structure and the first spiral-shaped structure have a common lateral geometry.

19. The semiconductor inductor structure (1400) of claim 14, wherein inner ends (214) of the first spiral-shaped structure and the second spiral-shaped structure are symmetrically disposed about a common point (210) in opposite directions.

20. The semiconductor inductor structure (1400) of claim 14, wherein at least a portion of the first spiral-shaped structure is symmetrical to the second spiral-shaped structure in an interlocking configuration spaced apart by the one or more intervening portions of the layer of dielectric material (606).
